(19) United States
(12) Patent Application Publication
(10) Pub. No.: US 2020/0173025 A1
(43) Pub. Date: Jun. 4, 2020

(54) Substrate Processing Apparatus

(71) Applicant: Kokusai Electric Corporation, Tokyo (JP)

(72) Inventor: Shuhei SAIDO, Toyama (JP)

(21) Appl. No.: 16/358,381

(22) Filed: Mar. 19, 2019

(30) Foreign Application Priority Data
Nov. 29, 2018 (JP) 2018-223188

(51) Int. Cl. C23C 16/50; C23C 16/455; H01L 21/285

(52) U.S. Cl. CPC C23C 16/50; H01L 21/28556; C23C 16/455

(57) ABSTRACT

Described herein is a technique capable of providing a quality of a film uniformly at upstream and downstream sides of a substrate. A substrate processing apparatus is provided that includes: a substrate support having a substrate placing surface on which a substrate is placed; a process chamber where the substrate is processed; a gas supply part provided at an upstream side of the process chamber to supply a gas to the process chamber; an exhaust part provided at a downstream side of the process chamber to exhaust an inner atmosphere of the process chamber; and an inclined portion configured as a part of the process chamber and extending continuously without a concave-convex structure or a hole to face the substrate placing surface from an upstream side to a downstream side of the substrate placing surface such that a cross sectional area of the process chamber is continuously and gradually decreases.

### CROSS REFERENCE TO RELATED APPLICATIONS

This application claims foreign priority under 35 U.S.C. § 119(a)-(d) to Application No. JP 2018-223188 filed on Nov. 29, 2018, the entire contents of which are hereby incorporated by reference.

### TECHNICAL FIELD

The present disclosure relates to a substrate processing apparatus.

### BACKGROUND

In a semiconductor manufacturing apparatus of manufacturing a semiconductor device, it is required to improve productivity. In order to improve the productivity, the yield should be improved by processing a substrate uniformly.

As an apparatus of processing the substrate such as the semiconductor manufacturing apparatus, for example, an apparatus of supplying a gas through a side portion of the substrate or an apparatus of supplying the gas from above the substrate may be used.

When the gas is supplied from above the substrate, the gas collides directly with a surface of the substrate. Therefore, for example, in a process of forming a film, the surface of the substrate may not be processed uniformly due to the problem such as a thickness of the film at a portion where the gas collides directly becomes thick.

When the gas is supplied in a lateral direction of the substrate, since the gas does not directly collide with the substrate, the problem described above does not occur. However, a state of the gas may change from an upstream side to a downstream side of the substrate. Thus, the quality of the film may be different between the upstream side and the downstream side of the substrate.

### SUMMARY

Described herein is a technique capable of providing a quality of a film uniformly at an upstream side and a downstream side of a substrate in an apparatus of supplying a gas in a lateral direction of the substrate.

According to one aspect of the technique of the present disclosure, there is provided a substrate processing apparatus, including: a substrate support having a substrate placing surface on which a substrate is placed; a process chamber where the substrate is processed; a gas supply part provided at an upstream side of the process chamber and configured to supply a gas to the process chamber; an exhaust part provided at a downstream side of the process chamber and configured to exhaust an inner atmosphere of the process chamber; and an inclined portion configured as a part of the process chamber and extending continuously without a concave-convex structure or a hole to face the substrate placing surface from an upstream side to a downstream side of the substrate placing surface such that a cross sectional area of the process chamber is continuously and gradually decreases.

### BRIEF DESCRIPTION OF THE DRAWINGS

FIG. 1 schematically illustrates a vertical cross-section of a substrate processing apparatus according to one or more embodiments described herein.

FIG. 2 schematically illustrates a cross-section taken along the line α-α of the substrate processing apparatus shown in FIG. 1.

FIG. 3 schematically illustrates a cross-section taken along the line β-β of the substrate processing apparatus shown in FIG. 1.

FIG. 4 schematically illustrates a gas flow in the substrate processing apparatus.

FIG. 5 schematically illustrates a simulation result of a flow velocity of a gas in the substrate processing apparatus.

FIG. 6 schematically illustrates a configuration of a first gas supply part of the substrate processing apparatus according to the embodiments described herein.

FIG. 7 schematically illustrates a configuration of a second gas supply part of the substrate processing apparatus according to the embodiments described herein.

FIG. 8 schematically illustrates a configuration of a third gas supply part of the substrate processing apparatus according to the embodiments described herein.

FIG. 9 is a block diagram schematically illustrating a configuration of a controller and components controlled by the controller of the substrate processing apparatus according to the embodiments described herein.

FIG. 10 is a flowchart illustrating a substrate processing performed by the substrate processing apparatus according to the embodiments described herein.

FIG. 11 schematically illustrates a processing state of the substrate according to the embodiments described herein.

FIG. 12 schematically illustrates a processing state of the substrate according to the embodiments described herein.

FIG. 13 schematically illustrates a processing state of the substrate according to a comparative example.

### DETAILED DESCRIPTION

### Embodiments

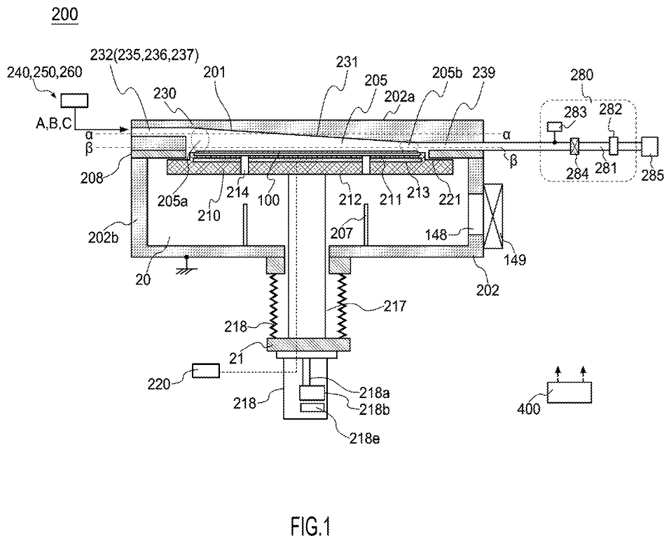

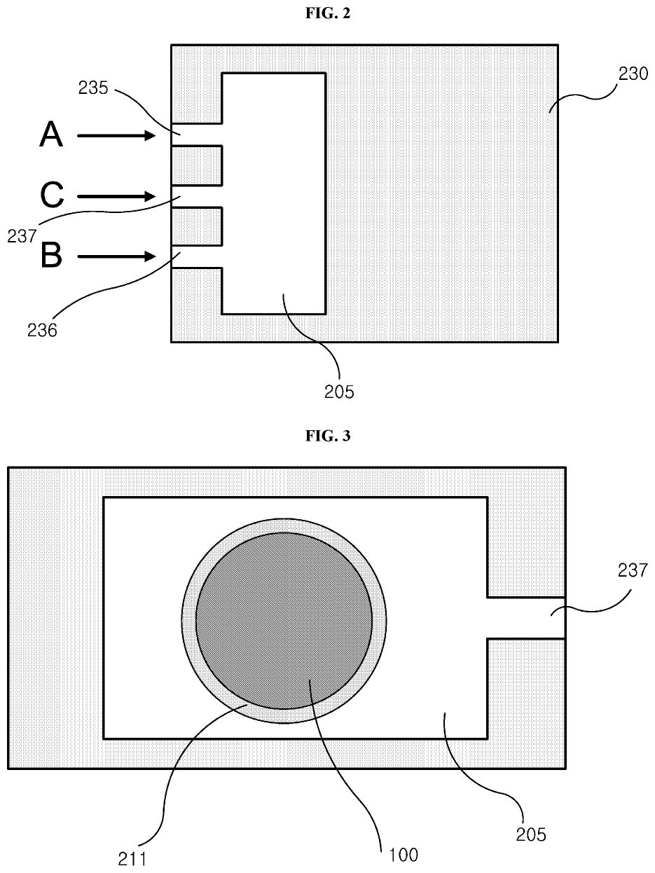

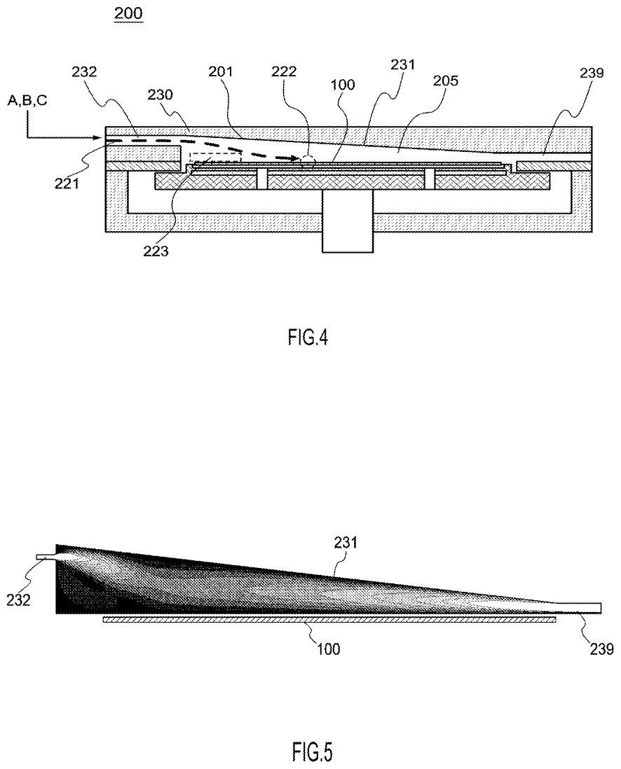

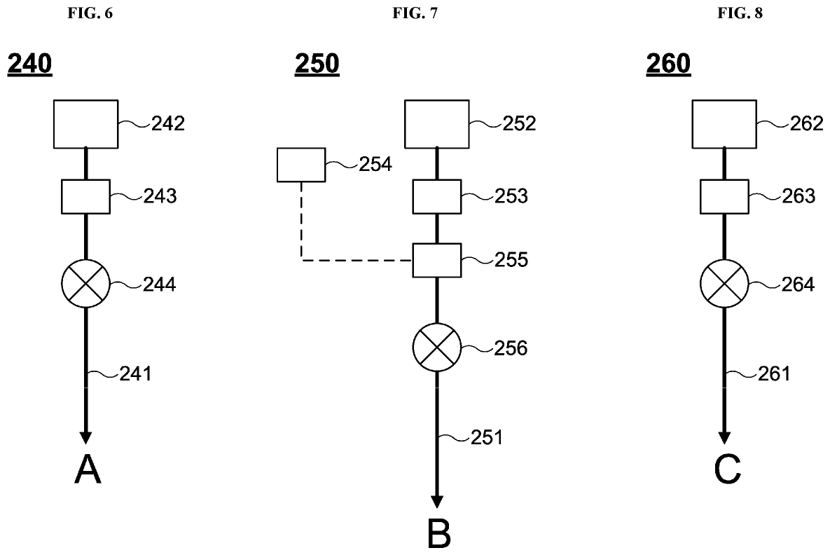

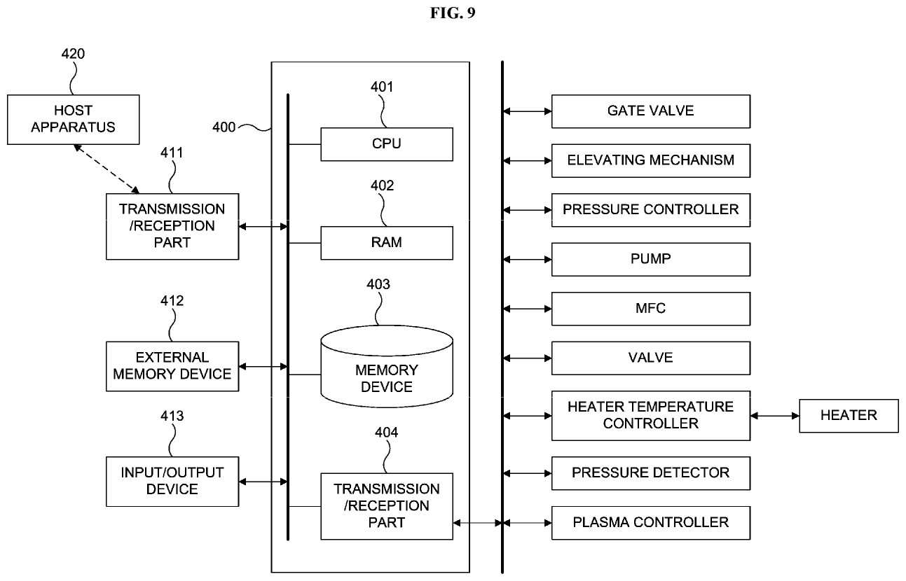

Hereinafter, one or more embodiments according to the technique will be described. An example of a substrate processing apparatus 200 of processing a substrate by supplying a gas will be described with reference to FIGS. 1 through 9. FIG. 1 schematically illustrates a vertical cross-section of the substrate processing apparatus 200 according to one or more embodiments described herein when viewed from a side thereof. FIG. 2 schematically illustrates a cross-section taken along the line α-α of the substrate processing apparatus 200 shown in FIG. 1 when viewed from above. FIG. 3 schematically illustrates a cross-section taken along the line β-β of the substrate processing apparatus 200 shown in FIG. 1 when viewed from above. FIG. 4 schematically illustrates a gas flow in the substrate processing apparatus 200. FIG. 5 schematically illustrates a simulation result of a flow velocity of the gas in the substrate processing apparatus 200. FIG. 6 schematically illustrates a configuration of a first gas supply part of the substrate processing apparatus 200. FIG. 7 schematically illustrates a configuration of a second gas supply part of the substrate processing apparatus 200. FIG. 8 schematically illustrates a configuration of a third gas supply part of the substrate processing apparatus 200. FIG. 9 is a block diagram schematically illustrating a configuration of a controller and components controlled by the controller of the substrate processing apparatus 200.

### Chamber

As shown in FIG. 1, the substrate processing apparatus 200 includes a chamber 202. The chamber 202 is configured as a sealed vessel. For example, the chamber 202 is made of a metal material such as aluminum (Al) and stainless steel (SUS). A process space 205 where a substrate 100 such as a silicon wafer is processed and a transfer space 206 through which the substrate 100 is transferred into the process space 205 are provided in the chamber 202. The chamber 202 includes an upper vessel 202a and a lower vessel 202b. A partition plate 208 is provided between the upper vessel 202a and the lower vessel 202b.

A substrate loading/unloading port 148 is provided on a side surface of the lower vessel 202b adjacent to a gate valve 149. The substrate 100 is transferred between a vacuum transfer chamber (not shown) and the transfer space 206 through the substrate loading/unloading port 148. Lift pins 207 are provided at the bottom of the lower vessel 202b. The lower vessel 202b is electrically grounded.

The process chamber 201 constituting the process space 205 is constituted by, for example, a ceiling 230 and a substrate support table 212 which will be described later. A substrate support 210 capable of supporting the substrate 100 is provided in the process space 205. The substrate support 210 mainly includes the substrate support table 212 having a substrate placing surface 211 on which the substrate 100 is placed and a heater 213 serving as a heating source embedded in the substrate support table 212.

Through-holes 214 penetrated by the lift pins 207 are provided at the substrate support table 212 corresponding to the locations of the lift pins 207. A temperature controller (also referred to as a “heater temperature controller”) 220 capable of controlling a temperature of the heater 213 is connected to the heater 213.

The substrate support table 212 is supported by a shaft 217. A support portion of the shaft 217 penetrates a hole provided at the bottom of the chamber 202. The shaft 217 is connected to an elevating mechanism 218 outside the chamber 202 via a support plate 216. The substrate 100 placed on the substrate placing surface 211 is elevated and lowered by operating the elevating mechanism 218 by elevating and lowering the shaft 217 and the substrate support table 212. Bellows 219 covers the periphery of a lower end of the shaft 217. As a result, the interior of the chamber 202 is maintained airtight.

The elevating mechanism 218 mainly includes a support shaft 218a supporting the shaft 217 and an actuator 218b configured to elevate or lower the support shaft 218a.

The elevating mechanism 218 may further include an instruction part 218e which is a part of the elevating mechanism 218 and configured to control the actuator 218b to elevate or lower the support shaft 218a. The instruction part 218e is electrically connected to a controller 400 described later. The actuator 218b may be controlled by the instruction part 218e based on an instruction from the controller 400. The actuator 218b is configured to control the substrate support table 212 to move to a substrate transfer position or a substrate processing position which will be described later.

When the substrate 100 is transferred, the substrate support table 212 is moved downward until the substrate placing surface 211 faces the substrate loading/unloading port 148. When the substrate 100 is processed, the substrate support table 212 is moved upward until the substrate 100 reaches the substrate processing position in the process space 205 as shown in FIG. 1.

The ceiling 230 is supported on the partition plate 208. The ceiling 230 is provided with an inclined portion 231 having an inclined surface. The inclined surface of the inclined portion 231 is provided where the inclined portion 231 faces the substrate placing surface. The inclined portion 231 may be integrated with the ceiling 230. However, when it is difficult to provide the inclined portion 231 integrated with the ceiling 230, the inclined portion 231 may be provided as a separate component.

A first gas supply hole 235, a second gas supply hole 236 and a third gas supply hole 237 are provided on a side surface of the ceiling 230. The first gas supply hole 235, the second gas supply hole 236 and the third gas supply hole 237 may be collectively referred to as a gas supply hole 232.

While the embodiments will be described by way of an example in which the gas supply hole 232 (that is, the first gas supply hole 235, the second gas supply hole 236 and the third gas supply hole 237) is provided at the ceiling 230, the embodiments are not limited thereto. It is sufficient that a gas can be supplied through a side portion of the process chamber 201. For example, other structure (for example, a block dedicated to the gas supply hole 232) may be installed to the ceiling 230 to provide the gas supply hole 232 therein, or to provide the gas supply hole 232 between the block and the ceiling 230.

As shown in FIG. 1, the first gas supply hole 235, the second gas supply hole 236 and the third gas supply hole 237 are provided higher than the substrate placing surface 211. In addition, the first gas supply hole 235, the second gas supply hole 236 and the third gas supply hole 237 are provided at the same height. As shown in FIG. 2, the first gas supply hole 235, the second gas supply hole 236 and the third gas supply hole 237 are adjacent to each other in the horizontal direction. The first gas supply hole 235 communicates with a first gas supply part (also referred to as a “line A” or a “first gas supply system”) 240 described later. The second gas supply hole 236 communicates with a second gas supply part (also referred to as a “line B” or a “second gas supply system”) 250 described later. The third gas supply hole 237 communicates with a third gas supply portion (also referred to as a “line C” or a “third gas supply system”) 260.

An exhaust flow path 239 is provided at a position opposite to the gas supply hole 232 with the substrate 100 therebetween. The exhaust flow path 239 is a flow path through which an inner atmosphere of the process chamber 201 is exhausted. For example, the exhaust flow path 239 is provided between the ceiling 230 and the partition plate 208. The exhaust flow path 239 communicates with an exhaust pipe 281 described later.

According to the configuration described above, the gas supply hole 232 is configured as an upstream portion of the process chamber 201, and the exhaust flow path 239 is configured as a downstream portion of the process chamber 201. The gas supplied through the gas supply hole 232 is moved to the exhaust flow path 239 through an upper region 205a of an upstream side of the substrate 100 and an upper region 205b of a downstream side of the substrate 100.

While the embodiments are described by way of an example in which the exhaust flow path 239 is provided between the ceiling 230 and the partition plate 208, the embodiments are not limited thereto. It is sufficient that the inner atmosphere of the process chamber 201 can be exhausted. For example, another structure other than the ceiling 230 (for example, a block dedicated to the exhaust flow path 239) may be installed to provide the exhaust flow path 239 therein, or to provide the exhaust flow path 239 between the block and the ceiling 230.

The inclined surface of the inclined portion 231 is inclined so that a distance from the substrate placing surface 211 to the inclined surface of the inclined portion 231 gradually decreases from an upstream side to a downstream side of the substrate placing surface 211. Specifically, the inclined surface of the inclined portion 231 gradually inclined from the upstream side to the downstream side of the substrate placing surface 211. That is, the inclined portion 231 extends continuously such that a cross sectional area of the process space 205 gradually decreases from the upstream side to the downstream side of the substrate placing surface 211.

Since the cross sectional area of the process space 205 and the flow velocity of the gas are inversely proportional, the gas flow becomes faster as the cross sectional area becomes smaller from the upstream side to the downstream side of the process space 205. Therefore, the gas flow becomes faster as the gas flows to the downstream side of the substrate 100. FIG. 5 schematically illustrates a simulation result of the flow velocity of the gas. In FIG. 5, the lower the brightness, the slower the gas flow, the higher the brightness, the faster the gas flow. According to the simulation result, the gas flow is fast in the vicinity of the gas supply hole 232 and in the vicinity of the exhaust flow path 239.

The inclined surface of the inclined portion 231 has a continuous shape without a concave-convex structure or a hole. With the inclined surface of the inclined portion 23 described above, it is possible to suppress the occurrence of a turbulent flow even when the gas supplied through the gas supply hole 232 collides with the inclined surface of the inclined portion 231.

If the concave-convex structure or the hole is provided at the inclined surface of the inclined portion 231, the turbulent flow occurs when the gas collides with a convex structure of the concave-convex structure or collides with a boundary of the hole. As a result, the gas having a non-uniform density is unintentionally supplied onto the substrate 100 by the turbulent flow of the gas. For example, in some cases, the density of the gas below the convex structure or the hole is high, and the density of the gas below a concave structure is lower than that of the gas below the convex structure or the hole.

The reason why the gas supply hole 232 is provided higher than the substrate placing surface 211 (that is, the substrate support table 212 or the substrate support 210) will be described below. If the gas supply hole 232 and the substrate 100 placed on the substrate support table 212 are provided at the same height, the supplied gas collides with a side surface of the substrate 100, and the turbulent flow of the gas occurs. When the turbulent flow occurs, the gas concentrates on a portion where the gas collides, and as a result, there is a problem such as a thickness of a film becomes thick only at the portion where the gas collides. However, when the gas supply hole 232 is provided higher than the substrate 100, the gas does not collide with the side surface of the substrate 100, so the turbulent flow may not occur. As a result, it is possible to process the surface of the substrate 100 uniformly.

When the gas in a plasma state is supplied through the second gas supply part 250, preferably, as shown in FIG. 4, the height of the gas supply hole 232 is set such that a landing point 222 of a main flow 221 (indicated by a dotted arrow in FIG. 4) of the gas supplied through the gas supply hole 232 is located on the surface of the substrate 100. The reason will be described below with reference to FIG. 4. FIG. 4 is a simplified view of the substrate processing apparatus of FIG. 1 in order to explain the gas flow. In the present specification, the main flow 221 of the gas refers to a flow of the gas having a plasma density higher than that of the other flow of the gas.

In an upstream region 223 of the landing point 222, the gas in the plasma state is supplied onto the substrate 100 by the diffusion of the gas. As shown in FIG. 5, since the gas flow is not so fast in the upstream region 223, it is possible to supply the components of the gas to an upstream edge of the substrate 100.

Since the landing point 222 of the main flow 221 is located on the surface of the substrate 100 as described above, a distance by which the plasma flows is defined by a distance from the landing point 222 to a downstream end of the substrate 100, and the distance by which the plasma flows can be shortened as compared with a case when the plasma is supplied in a lateral direction of the substrate 100. Therefore, the plasma which is deactivated in a short time can be used for processing the substrate 100.

### Gas Supply Part

As shown in FIGS. 1 and 2, the ceiling 230 is provided with the first gas supply hole 235 through which a source gas is supplied, the second gas supply hole 236 through which a reactive gas is supplied and the third gas supply holes 237 through which a purge gas is supplied. As will be described later, the reactive gas refers to a gas which reacts with the source gas. The first gas supply hole 235 may also be referred to as a source gas supply hole, the second gas supply hole 236 may also be referred to as a reactive gas supply hole, and the third gas supply hole 237 may also be referred to as a purge gas supply hole. The first gas supply part 240, the second gas supply part 250 and the third gas supply part 260 are collectively referred to as a gas supply part (also referred to as a gas supply system or a gas supply mechanism).

The first gas supply hole 235 is configured to communicate with a gas supply pipe 241 which is a part of the first gas supply part 240. The gas supply pipe 241 is fixed to the upper vessel 202a.

The second gas supply hole 236 is configured to communicate with a gas supply pipe 251 which is a part of the second gas supply part 250. The gas supply pipe 251 is fixed to the upper vessel 202a.

The third gas supply hole 237 is configured to communicate with a gas supply pipe 261 which is a part of the third gas supply part 260. The gas supply pipe 261 is fixed to the upper vessel 202a.

The symbol “A” shown in FIGS. 1 and 2 correspond to the symbol “A” shown in FIG. 6. Similarly, the symbol “B” corresponds to the symbol “B” shown in FIG. 7, and the symbol “C” corresponds to the symbol “C” shown in FIG. 8.

### First Gas Supply Part

Subsequently, the first gas supply part (also referred to as a first gas supply system or a first gas supply mechanism) 240 will be described in detail with reference to FIG. 6.

A first gas supply source 242, a mass flow controller (MFC) 243 serving as a flow rate controller (flow rate control mechanism) and a valve 244 serving as an opening/closing valve are provided at the gas supply pipe 241 in order from an upstream side to a downstream side of the gas supply pipe 241.

A gas contacting a first element (hereinafter, also referred to as a “first element-containing gas”) is supplied to the process chamber 201 through the gas supply pipe 241 provided with the MFC 243 and the valve 244.

The first element-containing gas is used as the source gas, that is, one of process gases. In the embodiments, the first element may include titanium (Ti). That is, the first element-containing gas may include a titanium-containing gas. Specifically, titanium chloride (TiCl₄) gas may be used as the titanium-containing gas.

When a source of the first element-containing gas is in liquid state at room temperature and under atmospheric pressure, a vaporizer (not shown) may be provided between the first gas supply source 242 and the MFC 243. However, the embodiments will be described by way of an example in which the source of the first element-containing gas is in gaseous state.

The first gas supply part 240 is constituted mainly by the gas supply pipe 241, the MFC 243 and the valve 244. The first gas supply part 240 may further include the first gas supply source 242. Since the first gas supply part 240 is configured to supply the source gas, the first gas supply part 240 may also be referred to as a source gas supply part.

### Second Gas Supply Part

Subsequently, the second gas supply part (also referred to as a second gas supply system or a second gas supply mechanism) 250 will be described in detail with reference to FIG. 7. A reactive gas supply source 252, an MFC 253 serving as a flow rate controller (flow rate control mechanism), a remote plasma unit (RPU) 255 serving as a plasma generator and a valve 256 are provided at the gas supply pipe 251 in order from an upstream side to a downstream side of the gas supply pipe 251.

The reactive gas (also referred to as a “second element-containing gas”) is supplied to the process chamber 201 through the gas supply pipe 251 provided with the MFC 253, the RPU 255 and the valve 256. The reactive gas is activated into a plasma state by the RPU 255. The RPU 255 is controlled by a plasma controller 254.

The reactive gas is one of the process gases. For example, the reactive gas may include a nitrogen (N)-containing gas. For example, ammonia (NH₃) gas may be used as the nitrogen-containing gas. The reactive gas refers to a gas which reacts with the components of the source gas.

When the plasma collides with a dispersion plate of the related art, the plasma may be deactivated. However, according to the embodiments described herein, no dispersion plate is provided. Therefore, the plasma is supplied onto the substrate 100 without being deactivated.

The second gas supply part 250 is constituted mainly by the gas supply pipe 251, the MFC 253, the valve 256 and the RPU 255. The second gas supply part 250 may further include the reactive gas supply source 252 and the plasma controller 254. Since the second gas supply part 250 is configured to supply the reactive gas, the second gas supply part 250 may also be referred to as a reactive gas supply part.

### Third Gas Supply Part

Subsequently, the third gas supply part (also referred to as a third gas supply system or a third gas supply mechanism) 260 will be described in detail with reference to FIG. 8. A purge gas supply source 262, an MFC 263 and a valve 264 serving as an opening/closing valve are provided at the gas supply pipe 261 in order from an upstream side to a downstream side of the gas supply pipe 261.

The purge gas is supplied to purge an atmosphere of the process space 205 (that is, the inner atmosphere of the process chamber 201) in purging steps described later. For example, nitrogen (N₂) gas is used as the purge gas.

The third gas supply part 260 is constituted mainly by the gas supply pipe 261, the MFC 263 and the valve 264. The third gas supply part 260 may further include the purge gas supply source 262. Since the third gas supply part 260 is configured to supply the purge gas, the third gas supply part 260 may also be referred to as a purge gas supply part.

### Exhaust Part

Subsequently, an exhaust part (also referred to as an exhaust system or an exhaust mechanism) 280 will be described in detail with reference to FIG. 1. The exhaust part 280 configured to exhaust the inner atmosphere of the process chamber 201 includes the exhaust pipe 281 communicating with the exhaust flow path 239. An APC (Automatic Pressure Controller) 282 serving as a pressure controller configured to adjust (control) a pressure of the process space 205 (that is, an inner pressure of the process chamber 201) to a predetermined pressure and a pressure detector 283 configured to measure the pressure of the process space 205 (the inner pressure of the process chamber 201) are provided at the exhaust pipe 281. The APC 282 includes a valve body (not shown) capable of adjusting the opening degree thereof. The APC 282 is configured to adjust the conductance of the exhaust pipe 281 in accordance with an instruction from the controller 400 described later. A valve 284 is provided at the exhaust pipe 261 on an upstream side of the APC 282. In addition, a bypass pipe (not shown) is connected to the exhaust pipe 281 at a downstream side of the APC 282. The exhaust pipe 281, the valve 284 and the APC 282 are collectively referred to as the exhaust part 280. The exhaust part 280 may further include the pressure detector 283.

A pump 285 is provided on a downstream side of the exhaust pipe 281. The pump 285 is configured to exhaust the inner atmosphere of the process chamber 201 through the exhaust pipe 281.

### Controller

The substrate processing apparatus 200 includes the controller 400 configured to control components of the substrate processing apparatus 200. As shown in FIG. 9, the controller 400 includes at least a CPU (Central Processing Unit) 401 serving as an arithmetic unit, a RAM (Random Access Memory) 402 serving as a temporary memory part, a memory device 403 and a transmission/reception part 404. The controller 400 is connected to the components of the substrate processing apparatus 200 via the transmission/reception part 404, calls a program or recipe from the RAM 402 or the memory device 403 in accordance with an instruction of a host controller (not shown) or a user, and controls the operations of the components of the substrate processing apparatus 200 according to the contents of the instruction. The controller 400 may be embodied by a dedicated computer or as a general-purpose computer. The controller 400 according to the embodiments may be embodied by: preparing an external memory device 412 (e.g. a magnetic tape, a magnetic disk such as a flexible disk and a hard disk, an optical disk such as a CD and a DVD, a magneto-optical disk such as MO and a semiconductor memory such as a USB memory (USB flash drive) and a memory card) storing the program or the recipe; and installing the program into the general-purpose computer using the external memory device 412. The means for providing the program to the computer (general-purpose computer) is not limited to the external memory device 412. The program may be supplied to the computer using communication means such as the Internet and a dedicated line. In addition, the program may be provided to the computer without using the external memory device 412 by receiving the information (i.e., program) from a host apparatus 420 via a transmission/reception part 411. A user can input an instruction to the controller 400 using an input/output device 413 such as a keyboard and a touch panel.

The memory device 403 or the external memory device 412 may be embodied by a non-transitory computer readable recording medium. Hereafter, the memory device 403 and the external memory device 412 are collectively referred to as recording media. In the present specification, the term “recording media” may refer to only the memory device 403, only the external memory device 412 or both of the memory device 403 and the external memory device 412.

### Substrate Processing

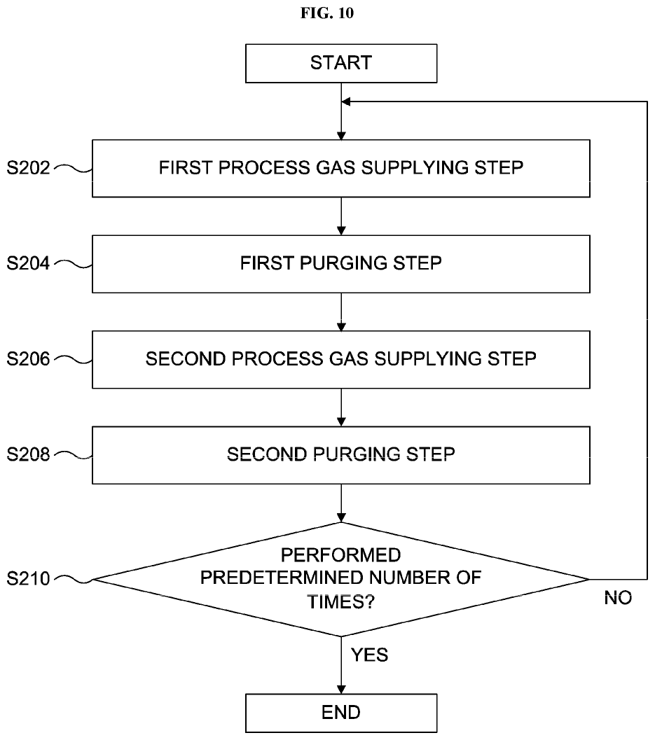

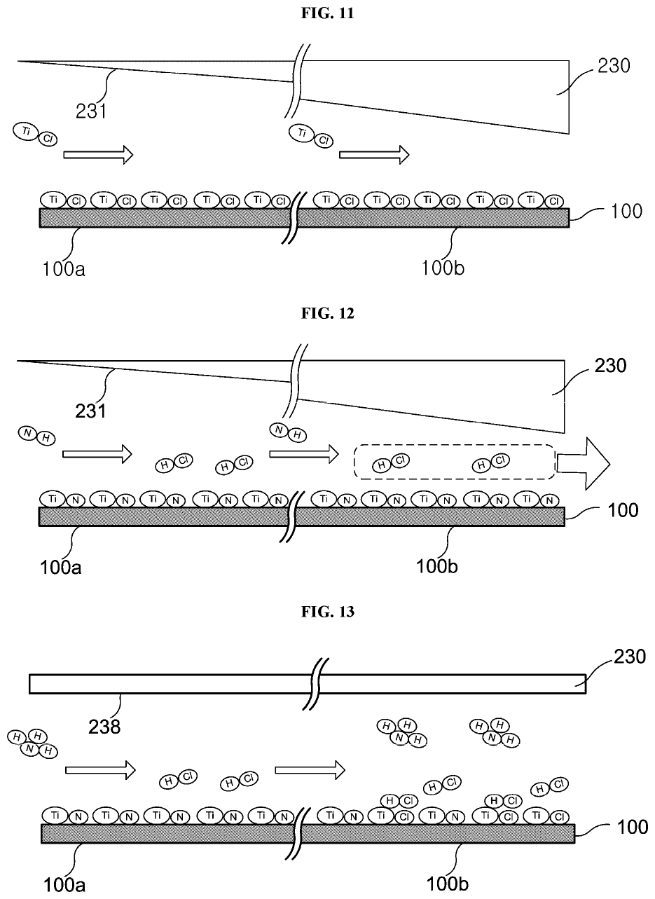

A substrate processing using the substrate processing apparatus 200 will be described with reference to FIGS. 10 through 12. FIG. 10 is a flowchart schematically illustrating the substrate processing. FIGS. 11 and 12 schematically illustrate a state of a film formed on the substrate 100 according to the embodiments described herein, and FIG. 12 schematically illustrates a state of the film formed on the substrate 100 according to a comparative example.

The film is formed on the substrate 100 by performing the substrate processing described above. In the following descriptions, the operations of the components constituting the substrate processing apparatus 200 are controlled by the controller 400.

### Substrate Loading Step

A substrate loading step will be described. In FIG. 10, the illustration of the substrate loading step is omitted. The substrate support table 212 of the substrate processing apparatus 200 is lowered to the position for transferring the substrate 100 (substrate transfer position) and the lift pins 207 penetrate the through-holes 214 of the substrate support table 212. As a result, the lift pins 207 protrude from the surface of the substrate support table 212 with a predetermined height. Subsequently, the gate valve 149 is opened to spatially connect the vacuum transfer chamber (not shown) to the transfer space 206. Then, the substrate 100 is loaded (transferred) into the transfer space 206 from the vacuum transfer chamber and placed on the lift pins 207 by a substrate transfer device (not shown). As a result, the substrate 100 is placed onto the lift pins 207 protruding from the surface of the substrate support table 212 and is supported by the lift pins 207 in horizontal orientation.

After the substrate 100 is transferred into the chamber 202, the substrate transfer device is retracted to the outside of the chamber 202, and the gate valve 149 is closed to seal the chamber 202. Thereafter, the substrate support table 212 is elevated to transfer the substrate 100 onto the substrate placing surface 211 and then further elevated until the substrate 100 is at the substrate processing position in the process space 205 described above.

After the substrate 100 is loaded into the transfer space 206, the valve 284 is opened to communicate the process space 205 with the APC 282. By adjusting the conductance of the exhaust pipe 281, the APC 282 controls (adjusts) an exhaust flow rate of the process space 205 by the pump 285, and maintains the pressure of the process space 205 (that is, the inner pressure of the process chamber 201) at a predetermined pressure (for example, a high vacuum of 10-5 Pa to 10-1 Pa).

When the substrate 100 is placed on the substrate support table 212, electrical power is supplied to the heater 213 embedded in the substrate support table 212 along the substrate placing surface such that a temperature (surface temperature) of the substrate 100 is adjusted to a predetermined temperature. The temperature of the substrate 100 may range, for example, from room temperature to 800° C., preferably from room temperature to 500° C. The controller 400 calculates a control value based on temperature information detected by a temperature sensor (not shown), and controls the temperature controller 220 to control the state of electric conduction to the heater 213 based on the calculated control value to adjust the temperature of the heater 213.

After elevating the temperature of the substrate 100 to a substrate processing temperature, the following substrate processing accompanied by a heat treatment process is performed while maintaining the temperature of the substrate 100 at a predetermined temperature. That is, the substrate 100 is processed by supplying the process gases into the chamber 202 through the gas supply pipes described above, respectively.

The substrate processing will be described by way of an example in which a titanium nitride film serving as the film is formed on the substrate 100 using titanium chloride (TiCl₄) gas serving as the first element-containing gas (first process gas) and ammonia (NH₃) gas serving as the reactive gas (second process gas). In the embodiments, an alternate supply process is performed in which steps of alternately supplying different process gases are repeated.

### First Process Gas Supplying Step S202

Subsequently, a first process gas supplying step S202 will be described. After the substrate support table 212 is moved to the substrate processing position shown in FIG. 1, the inner pressure of the process chamber 201 is adjusted by exhausting the inner atmosphere of the process chamber 201 from the process chamber 201 via the exhaust pipe 281. While adjusting the inner pressure of the process chamber 201 to a predetermined pressure, the substrate 100 is heated so that the temperature of the substrate 100 reaches a predetermined temperature, for example, 500° C. to 600° C.

Subsequently, an operation of the gas supply part will be described. The valve 244 of the first gas supply part 240 is opened and the flow rate of the first process gas is adjusted by the MFC 243 of the first gas supply part 240. By the operation described above, the first process gas is supplied into the process chamber 201 through the gas supply pipe 241. For example, the TiCl₄ gas serving as the first process gas is supplied into the process chamber 201. As shown in FIG. 11, by supplying the TiCl₄ gas, a titanium-containing layer is formed on the substrate 100. The titanium-containing layer is formed from an upstream portion 100a to a downstream portion 100b of the substrate 100.

The upstream portion 100a refers to a portion of the substrate 100 close to the gas supply hole 232, and the downstream portion 100b refers to a portion of the substrate 100 close to the exhaust flow path 239.

After a predetermined time has elapsed, the valve 244 is closed to stop the supply of the TiCl₄ gas.

### First Purging Step S204

Subsequently, the first purging step S204 will be described. After the supply of the TiCl₄ gas is stopped, the purge gas is supplied through the third gas supply part 260 to purge the inner atmosphere of the process chamber 201. In the first purging step S204, the valve 244 and the valve 256 are closed and the valve 264 is opened.

The inner pressure of the process chamber 201 is adjusted (controlled) by the APC 282 such that the inner pressure of the process chamber 201 reaches a predetermined pressure. As a result, the TiCl₄ gas which was not adhered to the substrate 100 in the first process gas supplying step S202 is removed from the process chamber 201 through the exhaust pipe 281 by the pump 285.

In the first purging step S204, a large amount of the purge gas may be supplied to the process chamber 201 to increase an exhaust efficiency of removing the TiCl₄ gas which was not adhered to the substrate 100 or the TiCl₄ gas remaining in the process chamber 201.

After a predetermined time has elapsed, the valve 264 is closed to terminate the first purging step S204.

### Second Process Gas Supplying Step S206

Hereinafter, a second process gas supplying step S206 will be described. First, the plasma controller 254 controls the RPU 255 such that the electric power is supplied to the RPU 255 to activate the gas passing through the RPU 255 into a plasma state by the RPU 255. When it takes time until the supply of the electric power is stabilized, the second process gas supplying step S206 may be performed in parallel with the previous step (for example, the first purging step S204).

After the purging of the inner atmosphere of the process chamber 201 is completed, the second process gas supplying step S206 is performed. The valve 256 of the second gas supply part 250 is opened, and the NH₃ gas serving as the second element-containing gas (also referred to as the reactive gas or the second process gas) is supplied into the process chamber 201 through the RPU 255 of the second gas supply part 250. In the second process gas supplying step S206, the flow rate of the NH₃ gas is adjusted by the MFC 253 of the second gas supply part 250 to a predetermined flow rate. For example, the flow rate the NH₃ gas may range from 1,000 sccm to 10,000 sccm.

The NH₃ gas activated into the plasma state by the RPU 255 is supplied into the process chamber 201 through the gas supply hole 236. The NH₃ gas supplied into the process chamber 201 reacts with the titanium-containing layer formed on the substrate 100. Then, the titanium-containing layer formed on the substrate 100 is modified (changed) by the plasma of the NH₃ gas. As a result, for example, a titanium nitride layer (hereinafter, also referred to as a “TiN layer”) which is a layer containing titanium (Ti) element and nitrogen (N) element is formed on the substrate 100.

Hereinafter, a state of the substrate 100 according to the comparative example will be described with reference to FIG. 13. Instead of the inclined portion 231 having the inclined surface according to the embodiments, the ceiling 230 according to the comparative example is provided with a parallel portion 238 having a surface parallel to the substrate 100.

When the NH₃ gas is supplied in the second process gas supplying step S206, the NH₃ gas is decomposed and the decomposed NH₃ gas reacts with the TiCl₄ component on the surface of the substrate 100 to form the TiN layer. While the TiN layer is formed, hydrogen chloride (HCl) is generated as by-products.

The by-products HCl generated in the upstream portion 100a of the substrate 100 flow toward the downstream portion 100b of the substrate 100. The by-products HCl are also generated in the downstream portion 100b, and the by-products HCl generated in the upstream portion 100a also flow into the downstream portion 100b.

Then, as shown in FIG. 13, an amount of the by-products HCl staying above the downstream portion 100b is larger than that of the by-products HCl staying above the upstream portion 100a. As described above, since the amount of the by-products HCl increases, the part of the HCl adheres to the TiCl₄ component on the surface of the substrate 100. Since the adhered HCl exists between the NH₃ gas and the TiCl₄ component, the adhered HCl interferes with the NH₃ gas binding to the TiCl₄ component.

The second process gas supplying step S206 is provided to form the TiN layer by reacting the NH₃ gas with the TiCl₄ component in the downstream portion 100b as in the upstream portion 100a. However, according to a structure of the comparative example, since the HCl adheres to a part of the TiCl₄ components on the downstream part 100b as described above, the NH₃ gas may not be bonded with the TiCl₄ component. Therefore, a portion where the TiN layer is not formed occurs in the downstream portion 100b. That is, the quality of the film varies between the upstream portion 100a and the downstream portion 100b of the substrate 100 according to the comparative example.

However, since the inclined portion 231 having the inclined surface is provided according to the embodiments, the gas flow becomes faster as the gas flows to the downstream side (downstream portion 100b) of the substrate 100. Therefore, the by-products HCl generated in the upstream portion 100a or the downstream portion 100b is exhausted without staying above the downstream portion 100b.

Since the by-products do not stay above the downstream portion 100b, the reaction between the NH₃ gas and the TiCl₄ component is performed even on the downstream portion 100b without interruption. Therefore, it is possible to form the TiN layer in the downstream portion 100b. In a manner described above, it is possible to uniformize the quality of the film on the upstream side (upstream portion 100a) and the downstream side (downstream portion 100b) of the substrate 100.

After a predetermined time has elapsed from the start of the supply of the NH₃ gas, the valve 256 is closed to stop the supply of the NH₃ gas. For example, the supply time of the NH₃ gas (that is, the time duration of supplying the NH₃ gas) may range, for example, from 2 seconds to 20 seconds.

### Second Purging Step S208

Subsequently, the second purging step S208 will be described. After the supply of the NH₃ gas is stopped, the second purging step S208 similar to the first purging step S204 described above is performed. The operations of the components of the substrate processing apparatus 200 in the second purging step S208 is similar to those of the components in the first purging step S204. Therefore, the detailed descriptions of the second purging step S208 are omitted.

### Determination Step S210

Subsequently, a determination step S210 will be described. After the second purging step S208 is completed, in the determination step S210, the controller 400 determines whether a cycle including the first process gas supplying step S202, the first purging step S204, the second process gas supplying step S206 and the second purging step S208 has been performed a predetermined number of times (n times). When the cycle has been performed the predetermined number of times (n times), the TiN layer having a desired thickness is uniformly formed on the surface of the substrate 100. When the controller 400 determines, in the determination step S210, that the cycle has been performed the predetermined number of times (n times) (“YES” in FIG. 10), the substrate processing shown in FIG. 10 is terminated.

### Substrate Unloading Step

Subsequently, a substrate unloading step will be described. After the TiN layer having the desired thickness is formed, the substrate support table 212 is lowered to move the substrate 100 to the substrate transfer position. Thereafter, the gate valve 149 is opened and the substrate 100 is unloaded (transferred) out of the chamber 202 by using the substrate transfer device (not shown).

### Other Embodiments

While the technique is described in detail by way of the embodiments, the above-described technique is not limited thereto. The above-described technique may be modified in various ways without departing from the gist thereof. For example, the embodiments are described by way of an example in which the titanium-containing gas is used as the first element-containing gas and the nitrogen-containing gas is used as the second element-containing gas. However, the above-described technique is not limited thereto. The above-described technique may be applied when other gases such as a metal-containing gas or an oxygen-containing gas may be used as the first element-containing gas or the second element-containing gas.

In addition, when the gases described above are prone to thermal decomposition, effects according to the embodiments are remarkable. For example, the gas prone to thermal decomposition may include, for example, monosilane (SiH₄) gas The SiH₄ gas may be used as the first element-containing gas.

When the gas prone to thermal decomposition is used as the first element-containing gas or the second element-containing gas, by providing the inclined portion having the inclined surface, the following effects can be obtained. Since it takes time for the heat to permeate throughout the gas prone to thermal decomposition, the decomposition of the gas prone to thermal decomposition starts gradually after reaching a thermal decomposition temperature. For example, the gas passing through a position close to the heater begins to decompose earlier and the gas passing through a position far from the heater begins to decompose more slowly. In the state described above, it takes a predetermined time to decompose entirely the gas prone to thermal decomposition.

When the flow rate is set such that a predetermined time or more elapses to move from the upstream portion 100a to the downstream portion 100b, since the predetermined time may not have elapsed in the upstream portion 100a, the decomposed amount of the gas in the upstream portion 100a is small. Since the predetermined time may have elapsed in the downstream portion 100b, the decomposed amount of the gas in the downstream portion 100b is large.

When the components of the gas decomposed in the downstream portion 100b are large as described above, the quality of the film varies between the upstream side and the downstream side due to the problem such as the film formed on the downstream portion 100b becomes thicker than that of the film formed on the upstream portion 100a.

However, by providing the inclined portion 231 having the inclined surface, the gas flow of the gas prone to thermal decomposition can be made faster on the downstream side of the substrate 100. As a result, it is possible to exhaust the gas before the predetermined time elapses. That is, it is possible to exhaust the gas before the gas decomposes entirely. Therefore, it is possible to uniformize the quality of the film on the upstream side and the downstream side of the substrate 100.

For example, the embodiments are described by way of an example in which the N₂ gas is used as the inert gas. However, the above-described technique is not limited thereto. The above-described technique may be applied when a rare gas such as helium (He) gas, neon (Ne) gas and argon (Ar) gas is used as the inert gas.

According to some embodiments in the present disclosure, it is possible to provide the quality of the film uniformly at the upstream side and the downstream side of the substrate in the apparatus of supplying the gas in a lateral direction of the substrate.

1. A substrate processing apparatus, comprising:
a substrate support having a substrate placing surface on which a substrate is placed;
a process chamber where the substrate is processed;
a gas supply part provided at an upstream side of the process chamber and configured to supply a gas to the process chamber;
an exhaust part provided at a downstream side of the process chamber and configured to exhaust an inner atmosphere of the process chamber;
an inclined portion configured as a part of the process chamber and extending continuously without a concave-convex structure or a hole to face the substrate placing surface from an upstream side to a downstream side of the substrate placing surface such that a cross sectional area of the process chamber is continuously and gradually decreases; and
a gas supply hole disposed at an upper portion of an upstream side of the process chamber substantially directly adjacent to the inclined portion with a vertical gap between the gas supply part and the substrate placing surface, such that the gas flows downward from the inclined portion toward the substrate placing surface,
wherein the gas supply part comprises:
a source gas supply part configured to supply a source gas via a first supply hole in a lateral direction of the substrate,
a reactive gas supply part configured to supply a reactive gas reacting with the source gas via a second gas supply hole in the lateral direction of the substrate at a supply timing different from that of the source gas, and
a purge gas supply part configured to supply a purge gas via a third gas supply hole between a supply of the source gas and a supply of the reactive gas, and
wherein a height of the first gas supply hole is equal to a height of the second gas supply hole.

2. (canceled)

3. The substrate processing apparatus of claim 1, wherein
the source gas supply part configured to supply the source gas through an upstream side of the substrate, and
the reactive gas supply part configured to supply the reactive gas reacting with the source gas through the upstream side of the substrate.

4. The substrate processing apparatus of claim 1, wherein the gas supply part is configured such that a landing point of a main flow of the gas is located on a surface of the substrate.

5. The substrate processing apparatus of claim 3, wherein the reactive gas is supplied onto the substrate in a plasma state, and a distance from a landing point of a main flow of the gas to a downstream end of the substrate is set such that the reactive gas in the plasma state is supplied without being deactivated.

6. The substrate processing apparatus of claim 5, wherein the source gas comprises a gas prone to thermal decomposition, and the substrate support further comprises a heater configured to heat the substrate and embedded in the substrate support along the substrate placing surface.

7. The substrate processing apparatus of claim 5, wherein the gas supply part is configured such that the landing point is located on a surface of the substrate.

8. The substrate processing apparatus of claim 1, wherein the source gas in the gas comprises a gas prone to thermal decomposition, and the substrate support further comprises a heater configured to heat the substrate and embedded in the substrate support along the substrate placing surface.

9. The substrate processing apparatus of claim 8, wherein the gas supply part is configured such that a landing point of a main flow of the gas is located on a surface of the substrate.

10. The substrate processing apparatus of claim 5, wherein the gas supply part is configured such that a landing point of a main flow of the gas is located on a surface of the substrate.

11. The substrate processing apparatus of claim 8, wherein
the source gas supply part configured to supply the source gas through an upstream side of the substrate; and
the reactive gas supply part configured to supply the reactive gas reacting with the source gas through the upstream side of the substrate.

12. The substrate processing apparatus of claim 11, wherein the gas supply part is configured such that a landing point of a main flow of the gas is located on a surface of the substrate.

13. The substrate processing apparatus of claim 1, wherein the reactive gas in the gas is supplied onto the substrate in a plasma state, and a distance from a landing point of a main flow of the gas to a downstream end of the substrate is set such that the reactive gas in the plasma state is supplied without being deactivated.

14. The substrate processing apparatus of claim 13, wherein the source gas in the gas comprises a gas prone to thermal decomposition, and the substrate support further comprises a heater configured to heat the substrate and embedded in the substrate support along the substrate placing surface.

15. The substrate processing apparatus of claim 14, wherein the gas supply part is configured such that the landing point of the main flow of the gas is located on a surface of the substrate.

16. The substrate processing apparatus of claim 13, wherein the gas supply part is configured such that the landing point is located on a surface of the substrate.

17. The substrate processing apparatus of claim 16, wherein the source gas in the gas comprises a gas prone to thermal decomposition, and the substrate support further comprises a heater configured to heat the substrate and embedded in the substrate support along the substrate placing surface.

18. The substrate processing apparatus of claim 17, wherein the gas supply part is configured such that a landing point of a main flow of the gas is located on a surface of the substrate.

19. The substrate processing apparatus of claim 3, wherein the gas supply part is configured such that a landing point of a main flow of the gas is located on a surface of the substrate.
